(19) United States
(12) Patent Application Publication
(10) Pub. No.: US 2010/0108140 A1
(43) Pub. Date: May 6, 2010

(54) DEVICE CAPABLE OF THERMALLY COOLING WHILE ELECTRICALLY INSULATING

(75) Inventors: Brian C. Auman, Pickerington, OH (US); Carl Haeger, Reynoldsburg, OH (US); Philip Roland Lacourt, Chillicothe, OH (US); Mark Elliott McAlees, Circleville, OH (US); Stanley Duane Merritt, Bear, DE (US); George Wyatt Prejean, Orange, TX (US); Harland Lee Tate, Golden, CO (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E. I. DU PONT DE NEMOURS AND COMPANY, Wilmington, DE (US)

(21) Appl. No.: 12/609,271

(22) Filed: Oct. 30, 2009

Related U.S. Application Data
(63) Continuation-in-part of application No. 12/369,771, filed on Feb. 12, 2009.
(60) Provisional application No. 61/036,506, filed on Mar. 14, 2008.

(51) Int. Cl. H01L 31/042

(52) U.S. Cl. 136/256

(57) ABSTRACT

The present disclosure relates to a device for thermally cooling while electrically insulating. The device contains a first adhesive layer, substrate, a second adhesive layer and a heat sink. The first adhesive layer and the second adhesive layer are a vinyl or acrylic based polymer. The adhesive layers and the substrate may contain thermally conductive fillers, light absorbing pigments or mixtures of both.

### CROSS REFERENCE TO RELATED APPLICATION

This continuation-in-part patent application claims priority to U.S. patent application Ser. No. 12/369,771 filed Feb. 12, 2009 which claims benefit of U.S. provisional application No. 61/036,506 filed Mar. 14, 2008.

### FIELD OF DISCLOSURE

The present disclosure relates generally to multilayer device for thermal dissipation and electrical insulation. More specifically, the device comprises a filled polymeric film that can be bonded to a metal heat sink on one side and to an electronic component on the other, thereby electrically insulating the electronic component while also conducting heat away from the circuit.

### BACKGROUND OF THE DISCLOSURE

In the field of electronic components, including photovoltaic cells, both heat dissipation and electrical insulation are becoming increasingly important. Integrated circuits are increasingly being manufactured at smaller feature dimensions and higher densities, resulting in an increased need for thermal dissipation and electrical insulation. Similarly, thermal dissipation and electrical insulation are also important for photovoltaic systems, which tend to require a highly (electrically) insulated environment for collecting and distributing electrical current and also tend to lose operational efficiency with increasing temperature.

A need exists for a device that: i. provides acceptable bond strength under elevated temperatures and humidity; ii. has acceptable electrical insulation properties; iii. can withstand relatively high voltages, iv. resists degradation due to light; and/or v. also has acceptable thermal conductivity.

### SUMMARY

The present disclosure is directed to a device for thermally cooling while electrically insulating. The device contains a first adhesive layer, polymeric substrate, a second adhesive layer and a heat sink. The first adhesive layer and the second adhesive layer each have 68 to 100 weight percent vinyl or acrylic based polymer. The substrate has at least one polymeric layer.

### DETAILED DESCRIPTION OF THE PREFERRED EMBODIMENT(S)

The present disclosure is directed to a device for thermally cooling while electrically insulating. In one embodiment, the device has a first adhesive layer having a top surface and a bottom surface, the first adhesive layer comprising an amount from 68 to 100 weight percent vinyl or acrylic based polymer. The device has a substrate comprising at least one polymeric layer comprising:
i. 30 to 95 weight percent of a polymer selected from the group consisting of polyamide imides, polyether imides, polyaramids, polyamides, polysulfones, polyether ketones, liquid crystal polymers, polyesters, fluoropolymers, silicone resins, epoxy resins, cyanate esters, bismaleimide resins, bistriazines resins, polyphenylene sulfide, polyphenylene oxide and mixtures thereof; and
ii. 5 to 70 weight percent thermally conductive filler,
   The first adhesive bottom surface is directly bonded to the substrate. The device has a second adhesive layer having a top surface and a bottom surface, the second adhesive layer top surface being directly bonded to the substrate opposite of the first adhesive layer. The second adhesive layer comprising an amount from 68 to 100 weight percent vinyl or acrylic based polymer. The device also has a metal heat sink having a top surface and a bottom surface, the heat sink top surface being directly bonded to the second adhesive layer bottom surface.

The device is well suited for cooling and insulating electrical components. The term “electrical components” herein denotes but is not limited to integrated circuit devices plus other active and passive components like resistors, capacitors, inductors, transistors, diodes, and photovoltaic cells. The device of the present disclosure is particularly well suited for photovoltaic cells that utilize a light concentrator. In some embodiments, the semiconducting layer (metalized layer or contact grid) of a photovoltaic cell is directly bonded to the first adhesive layer top surface. The term “bonded”, “bonding” or any other variation thereof is synonymous with “adhered” or “adhesion” and the terms may be used interchangeably. The devices of the present disclosure tend to: i. maintain good bond strength under high temperatures, ii. provide useful electrical insulation, iii. provide high voltage resistance, iv. provide useful resistance to degradation under exposure to light, and v. provide adequate thermal conductivity.

### Adhesive Layers

The present disclosure comprises a first adhesive layer and a second adhesive layer. In some embodiments, the first adhesive layer and second adhesive layer are the same material. In some embodiments, they are different materials. The first adhesive layer and the second adhesive layer have an amount between (and optionally including) any two of the following weight percentages of vinyl or acrylic based polymer: 68, 70, 72, 74, 76, 78, 80, 82, 84, 86, 88, 90, 92, 94, 96, 98 and 100 weight percent. Acrylic polymers are defined as polymers based on acrylic acid and derivatives thereof. In some embodiments, the adhesive polymer is crosslinkable. In another embodiment, the adhesive polymer is extrudable or coatable. In some embodiments, the first adhesive layer and second adhesive layer are independently selected from the group consisting of:
ethylene vinyl acetate copolymer with adhesion promoter,
ethylene vinyl acetate glycidyl acrylate terpolymer,
ethylene vinyl acetate glycidyl methacrylate terpolymer,
ethylene alkyl acrylate copolymers with adhesion promoter,
ethylene alkyl methacrylate copolymers with adhesion promoter,
ethylene glycidyl acrylate,
ethylene glycidyl methacrylate,
ethylene alkyl acrylate glycidyl acrylate terpolymer,
ethylene alkyl methacrylate glycidyl acrylate terpolymer,
ethylene alkyl acrylate maleic anhydride terpolymers,
ethylene alkyl methacrylate maleic anhydride terpolymers
ethylene alkyl acrylate glycidyl methacrylate terpolymers,
ethylene alkyl methacrylate glycidyl methacrylate terpolymers,
alkyl acrylate acrylonitrile acrylic acid terpolymers including salts thereof,
alkyl acrylate acrylonitrile methacrylic acid terpolymers including salts thereof,
ethylene acrylic acid copolymer including salts thereof,
ethylene methacrylic acid copolymer including salts thereof,
alkyl acrylate acrylonitrile glycidyl methacrylate terpolymers,
alkyl methacrylate acrylonitrile glycidyl methacrylate terpolymers,
alkyl acrylate acrylonitrile glycidyl acrylate terpolymers,
alkyl methacrylate acrylonitrile glycidyl acrylate terpolymers,
polyvinyl butyral,
ethylene alkyl acrylate methacrylic acid terpolymers including salts thereof,
ethylene alkyl methacrylate methacrylic acid terpolymers including salts thereof,
ethylene alkyl acrylate acrylic acid terpolymers including salts thereof mixtures thereof,
ethylene alkyl methacrylate acrylic acid terpolymers including salts thereof,
ethylene ethyl hydrogen maleate,
ethylene alkyl acrylate ethyl hydrogen maleate,
ethylene alkyl methacrylate ethyl hydrogen maleate,
   and mixtures thereof.
   The ethylene vinyl acetate copolymer (EVA) of this disclosure includes formulated EVA which contains an organic peroxide such as TBEC (OO-tert-butyl O-(2-ethylhexyl)monoperoxycarbonate), a UV absorber such as the benzotriazole type or benzophenone type, a hindered amine light stabilizer such as bis(2,2,6,6,-tetramethyl-4-piperidyl)sebaceate (Tinuvin® 770 from CIBA), primary or secondary antioxidants such as hindered phenols and phosphites respectively, a mixture of primary and secondary antioxidants and an organo functional silane adhesion promoter such as methacryloxypropyl trimethoxysilane (Z-6030 from Dow Corning). In another embodiment, the formulated EVA is BIXCURE® from Bixby International Corporation, Newburyport, Mass. or Etimex Vistasolar 486/486.1 from Etimex Vistasolar, D-89165 Dietenheim Germany.

There is a practical limit to the thickness of the adhesive layers. The adhesive layers should be thin enough to not adversely impact thermal dissipation, thus allowing heat to pass efficiently to the heat sink. Adhesive layers should also provide reliable bonding between the substrate and the heat sink, as well as any electrical component to which the first adhesive top layer is bonded, at elevated temperatures and humidity. In some embodiments, the first adhesive layer and the second adhesive layer thickness are each between (and optionally including) any two of the following thicknesses: 6.25, 7, 8, 9, 10, 15, 20, 25, 30, 35, 40, 45, 50, 55, 60, 65, 70 and 75 microns. In some embodiments, the adhesive layers provide bond strength of at least 370 g/cm (2.07 PLI) and preferably higher than 740 g/cm (4.14 PLI). The bond strength should also be maintained at a level of at least 370 g/cm over the life of the component under conditions of elevated temperature and humidity. These conditions will depend on the particular component and the application in which it is used.

In some embodiments, the first adhesive layer and the second adhesive layer additionally comprise a filler selected from the group consisting of thermally conductive filler, light absorbing pigment and mixtures thereof. In some embodiments, the first adhesive layer and the second adhesive layer contain the same thermally conductive fillers or light absorbing pigments or mixtures thereof. In another embodiment, the first adhesive layer and the second adhesive layer contain different thermally conductive fillers or light absorbing pigments or mixtures thereof. In yet another embodiment, the thermally conductive filler and the light absorbing pigment may be the same material when the material can perform both functions. In some embodiments, the amount of thermally conductive filler in the first adhesive layer is between (and optionally including) any two of the following numbers: 0, 1, 2, 3, 4, 5, 10, 15, 20, 25, 30, 31 and 32 weight percent. In some embodiments, the amount of thermally conductive filler in the second adhesive layer is between (and optionally including) any two of the following numbers: 0, 1, 2, 3, 4, 5, 10, 15, 20, 25, 30, 31 and 32 weight percent.

In some embodiments, both the first and second adhesive layers contain a light absorbing pigment. In another embodiment, the first adhesive layer contains a light absorbing pigment. In another embodiment, the second adhesive layer contains a light absorbing pigment. In some embodiments, a light absorbing pigment may or may not be present in the first or second adhesive layer. In some embodiments, the light absorbing pigment in the first adhesive layer is between (and optionally including) any two of the following numbers: 0, 5, 10, 15 and 20 weight percent. In some embodiments, the light absorbing pigment in the second adhesive layer is between (and optionally including) any two of the following numbers: 0, 5, 10, 15 and 20 weight percent.

In one embodiment, filler can be added to the adhesive resin in a cast extrusion process. In another embodiment, the filler could be added during cast extrusion from a gravimetric feeder. Any conventional method may be used to add the thermally conductive filler and the light absorbing pigment to the adhesive resin. In some embodiments, the first and second adhesive layers contain other additives such as, antioxidants, crosslinking agents, adhesion promoters and other common additives known in the art. In some embodiments, an organo functional silane adhesion promoter is used. In another embodiment, an alkyl titanate adhesion promoter is used.

The adhesive layers of the present disclosure have an advantage over pressure sensitive adhesives used in the prior art. The adhesive layers of the present disclosure will have better heat resistance and cohesive strength. In addition, the adhesive layers of the present disclosure are integrated films, thus are more suitable for a continuous manufacturing process.

### Substrate

The substrate of the present disclosure provide an electrically insulating layer to prevent undesired electrical communication between an electrical component and the heat sink. The substrate of the present disclosure allows high electrical insulation (high breakdown voltage), resists degradation under exposure to light and provides acceptable thermal conductivity or low thermal impedance, generally allowing an electronic component to operate at temperatures between and optionally including: 20, 30, 40, 50, 60, 70 and 80 degrees C. This is particularly true when the electrical component is a photovoltaic cell utilizing a light concentrator. Temperatures can reach 100 degrees centigrade or higher at peak operating conditions under highly concentrated light. High voltages, according to the present disclosure, are voltages in excess of 1000 volts DC or in some applications, greater than 2000 volts DC. Typically, breakdown voltages of 250 v/mil or higher are desirable.

In some embodiments, the substrate of the present disclosure has one polymer layer. In another embodiment, the substrate contains at least two polymer layers. In some embodiments, the substrate of the present disclosure has a first polymer layer and a second polymer layer. In some embodiments, the first polymer layer and the second polymer layer are directly bonded to each other. In some embodiments, an adhesive layer is used to bond the first polymer layer to the second polymer layer. In some embodiments, the first polymer layer and the second polymer layer are the same polymer or different. In some embodiments, the substrate of the present disclosure is selected from a group consisting of: polyamide imides, polyether imides, polyaramids, polyamides and mixtures thereof. In some embodiments, the substrate is a polyester. In another embodiment, the polyester is selected from the group consisting of: polyethylene terephthalate, polyethylene naphthalate and mixtures thereof. In some embodiments, the substrate is selected from the group consisting of: polysulfones, polyether ketones, liquid crystal polymers, polyphenylene sulphides, polyphenylene oxide and mixtures thereof. In some embodiments, useful liquid crystal polymers are aromatic polyesters such as Zenite® from Dupont Xydar® from Solvay Advanced Polymers or Vectra® from Ticona. In another embodiment, the substrate is selected from the group consisting of: fluoropolymers, silicone resins, epoxy resins, cyanate esters, bismaleimide resins, bistriazine resins and mixtures thereof.

In some embodiments, the substrate is a polyimide. The polyimide substrate of the present disclosure has at least two polyimide layers, a first polyimide layer and a second polyimide layer. In some embodiments, the first polyimide layer and the second polyimide layer are directly bonded to each other. In some embodiments, the first polyimide layer and the second polyimide layer are the same polyimide or different. The polyimide layers provide thermal conduction and electrical insulation properties. The first polyimide layer and the second polyimide layer each comprise an amount between (and optionally including) any two of the following weight percentages of polyimide: 40, 45, 50, 55, 60, 65, 70, 75, 80, 85 and 90 weight percent polyimide. The polyimide is derived from at least one aromatic dianhydride and at least one aromatic diamine, the aromatic diamine being at least 80 mole percent of the total moles of diamine incorporated into the polyimide and the aromatic dianhydride being at least 80 mole percent of the total moles of dianhydride incorporated into the polyimide. In some embodiments, the polyimide is a wholly aromatic polyimide. In some embodiments, the polyimide layers may be corona treated to aid in bonding.

In some embodiments, the aromatic dianhydride polyimide precursor of the present disclosure is selected from a group consisting of:
1. pyromellitic dianhydride (PMDA);
2. 3,3′,4,4′-biphenyl tetracarboxylic dianhydride (BPDA);
3. 3,3′,4,4′-benzophenone tetracarboxylic dianhydride (BTDA);
4. 4,4′-oxydiphthalic anhydride (ODPA);
5. 3,3′,4,4′-diphenylsulfone tetracarboxylic dianhydride (DSDA);
6. 2,2-bis(3,4-dicarboxyphenyl) 1,1,1,3,3,3-hexafluoropropane dianhydride (6FDA);
7. 4,4′-(4,4′-isopropylidenediphenoxy)bis(phthalic anhydride) (BPADA);
8. 2,3,6,7-naphthalene tetracarboxylic dianhydride;
9. 1,2,5,6-naphthalene tetracarboxylic dianhydride;
10. 1,4,5,8-naphthalene tetracarboxylic dianhydride;
11. 2,6-dichloronaphthalene-1,4,5,8-tetracarboxylic dianhydride;
12. 2,7-dichloronaphthalene-1,4,5,8-tetracarboxylic dianhydride;
13. 2,3,3′,4′-biphenyl tetracarboxylic dianhydride;
14. 2,2′,3,3′-biphenyl tetracarboxylic dianhydride;
15. 2,3,3′,4′-benzophenone tetracarboxylic dianhydride;
16. 2,2′,3,3′-benzophenone tetracarboxylic dianhydride;
17. 2,2-bis(3,4-dicarboxyphenyl)propane dianhydride;
18. 1,1-bis(2,3-dicarboxyphenyl)ethane dianhydride;
19. 1,1-bis(3,4-dicarboxyphenyl)ethane dianhydride;
20. bis-(2,3-dicarboxyphenyl)methane dianhydride;
21. bis-(3,4-dicarboxyphenyl)methane dianhydride;
22. 4,4′-(hexafluoroisopropylidene)diphthalic anhydride;
23. bis-(3,4-dicarboxyphenyl)sulfoxide dianhydride;
24. tetrahydrofuran-2,3,4,5-tetracarboxylic dianhydride;
25. pyrazine-2,3,5,6-tetracarboxylic dianhydride;
26. thiophene-2,3,4,5-tetracarboxylic dianhydride;
27. phenanthrene-1,8,9,10-tetracarboxylic dianhydride;
28. perylene-3,4,9,10-tetracarboxylic dianhydride;
29. bis-1,3-isobenzofurandione;
30. bis-(3,4-dicarboxyphenyl)thioether dianhydride;
31. bicyclo[2,2,2]oct-7-ene-2,3,5,6-tetracarboxylicdianhydride;
32. 2-(3′,4′-dicarboxyphenyl) 5,6-dicarboxybenzimidazole dianhydride;
33. 2-(3′,4′-dicarboxyphenyl) 5,6-dicarboxybenzoxazole dianhydride;
34. 2-(3′,4′-dicarboxyphenyl) 5,6-dicarboxybenzothiazole dianhydride;
35. bis-(3,4-dicarboxyphenyl) 2,5-oxadiazole 1,3,4-dianhydride;
36. bis-2,5-(3′,4′-dicarboxydiphenylether) 1,3,4-oxadiazole dianhydride;
37. bis-2,5-(3′,4′-dicarboxydiphenylether) 1,3,4-oxadiazole dianhydride;
38. 5-(2,5-dioxotetrahydro)-3-methyl-3-cyclohexene-1,2-dicarboxylic anhydride;
39. trimellitic anhydride 2,2-bis(3′,4′-dicarboxyphenyl)propane dianhydride;
40. 1,2,3,4-cyclobutane dianhydride;
41. 2,3,5-tricarboxycyclopentylacetic acid dianhydride;
   and mixtures thereof.

In some embodiments, the aromatic diamine of the present disclosure is selected from a group consisting of:
1. 4,4′-diaminodiphenyl ether (4,4′-ODA);
2. 3,4′-diaminodiphenyl ether (3,4′-ODA);
3. 1,3-bis-(4-aminophenoxy)benzene (APB-134 or RODA);
4. 1,3-bis-(3-aminophenoxy)benzene (APB-133);
5. 1,2-diaminobenzene (OPD);
6. 1,3-diaminobenzene (MPD);
7. 1,4-diaminobenzene (PPD);
8. 2,2 bis-(4-aminophenyl)propane;
9. 4,4′-diaminodiphenyl methane;
10. 4,4′-diaminodiphenyl sulfide (4,4′-DDS);
11. 3,3′-diaminodiphenyl sulfone (3,3′-DDS);
12. 4,4′-diaminodiphenyl sulfone;
13. 1,2-bis-(4-aminophenoxy)benzene;
14. 1,2-bis-(3-aminophenoxy)benzene;
15. 1,4-bis-(4-aminophenoxy)benzene;
16. 1,4-bis-(3-aminophenoxy)benzene;
17. 1,5-diaminonaphthalene;
18. 1,8-diaminonaphthalene;
19. 2,2′-bis(trifluoromethyl)benzidine;
20. 4,4′-diaminodiphenyldiethylsilane;
21. 4,4′-diaminodiphenylsilane;
22. 4,4′-diaminodiphenylethylphosphine oxide;
23. 4,4′-diaminodiphenyl-N-methyl amine;
24. 4,4′-diaminodiphenyl-N-phenyl amine;
25. 2,5-dimethyl-1,4-diaminobenzene;
26. 2-(trifluoromethyl)-1,4-phenylenediamine;
27. 5-(trifluoromethyl)-1,3-phenylenediamine;
28. 2,2-Bis[4-(4-aminophenoxy)phenyl]-hexafluoropropane (BDAF);
29. 2,2-bis(3-aminophenyl) 1,1,1,3,3,3-hexafluoropropane;
30. benzidine;
31. 4,4′-diaminobenzophenone;
32. 3,4′-diaminobenzophenone;
33. 3,3′-diaminobenzophenone;
34. m-xylylene diamine;
35. bisaminophenoxyphenylsulfone;
36. 4,4′-isopropylidenedianiline;
37. N,N-bis-(4-aminophenyl)methylamine;
38. N,N-bis-(4-aminophenyl)aniline
39. 3,3′-dimethyl-4,4′-diaminobiphenyl;
40. 4-aminophenyl-3-aminobenzoate;
41. 2,4-diaminotoluene;
42. 2,5-diaminotoluene;
43. 2,6-diaminotoluene;
44. 2,4-diamine-5-chlorotoluene;
45. 2,4-diamine-6-chlorotoluene;
46. 4-chloro-1,2-phenylenediamine;
47. 4-chloro-1,3-phenylenediamine;
48. 2,4-bis-(beta-amino-t-butyl)toluene;
49. bis-(p-beta-amino-t-butyl phenyl)ether;
50. p-bis-2-(2-methyl-4-aminopentyl)benzene;
51. 1-(4-aminophenoxy)-3-(3-aminophenoxy)benzene;
52. 1-(4-aminophenoxy)-4-(3-aminophenoxy)benzene;
53. 2,2-bis-[4-(4-aminophenoxy)phenyl]propane (BAPP);
54. bis-[4-(4-aminophenoxy)phenyl]sulfone (BAPS);
55. 2,2-bis[4-(3-aminophenoxy)phenyl]sulfone (m-BAPS);
56. 4,4′-bis-(aminophenoxy)biphenyl (BAPB);
57. bis-(4-[4-aminophenoxy]phenyl)ether (BAPE);
58. 2,2′-bis-(4-aminophenyl)-hexafluoropropane (6F diamine);
59. bis(3-aminophenyl)-3,5-di(trifluoromethyl)phenylphosphine oxide
60. 2,2′-bis-(4-phenoxy aniline) isopropylidene;
61. 2,4,6-trimethyl-1,3-diaminobenzene;
62. 4,4′-diamino-2,2′-trifluoromethyl diphenyloxide;
63. 3,3′-diamino-5,5′-trifluoromethyl diphenyloxide;
64. 4,4′-trifluoromethyl-2,2′-diaminobiphenyl;
65. 4,4′-oxy-bis-[(2-trifluoromethyl)benzene amine];
66. 4,4′-oxy-bis-[(3-trifluoromethyl)benzene amine];
67. 4,4′-thio-bis-[(2-trifluoromethyl)benzene-amine];
68. 4,4′-thiobis-[(3-trifluoromethyl)benzene amine];
69. 4,4′-sulfoxyl-bis-[(2-trifluoromethyl)benzene amine];
70. 4,4′-sulfoxyl-bis-[(3-trifluoromethyl)benzene amine];
71. 4,4′-keto-bis-[(2-trifluoromethyl)benzene amine];
72. 9,9-bis(4-aminophenyl)fluorene;
73. 1,3-diamino-2,4,5,6-tetrafluorobenzene;
74. 3,3′-bis(trifluoromethyl)benzidine;
   and mixtures thereof.

The polymer (or combination of polymers) used for the substrate of the present disclosure, weather a single polymer layer or multiple polymer layers, are selected to achieve acceptable bond strength (typically at least 2 pli) under elevated temperatures and humidity, high electrical insulation, withstand relatively high voltages, resist degradation due to light, and have high thermal conductivity. In some embodiments, high thermal conductivity is intended to mean at least 0.3 W/mK. In another embodiment, the thermal impedance is sufficient to keep the temperature below 100 degrees C., preferably below 80 degrees C., more preferably below 60 degrees C. Thermal impedance of a film or layer will depend on the thickness of the film and the thermal conductivity. Generally, the thinner the film the lower the thermal impedance, but the dielectric strength will also decrease. The desired balance of properties will depend on the electrical application in which the device of the present disclosure is used.

In some embodiments, the polymer layers may be corona or plasma treated to aid in bonding.

In some embodiments, the substrate layer(s) comprises an amount between (and optionally including) any two of the following weight percentages of thermally conductive filler: 5, 10, 15, 20, 25, 30, 35, 40, 45, 50, 55, 60, 65 and 70 weight percent of a thermally conductive filler. The thermally conductive filler is added to decrease the thermal impedance (increase the thermal conductivity) of the substrate thus increasing efficiency of thermal transfer to the heat sink. The ability to efficiently dissipate heat from an electronic component, more specifically, a photovoltaic cell is important as it is known that the performance of photovoltaic materials decrease with elevated temperatures. In some embodiments, the thermally conductive filler used in the substrate is the same as the thermally conductive filler used in the adhesive layers. In another embodiment, the thermally conductive filler used in the substrate may be different from the thermally conductive filler used in the adhesive layers.

The term “thermal conductivity” herein denotes a measure of the ability of a material to transfer heat; given two surfaces on either side of the material with a temperature difference between them.

In some embodiments, substrate additionally comprises from between (and optionally including) any two of the following numbers: 1, 5, 10, 15 and 20 weight percent light absorbing pigment. In some embodiments, the light absorbing pigment in the substrate is the same as the light absorbing pigment in the adhesive layers. In other embodiments, the light absorbing pigment in the substrate is the different than the light absorbing pigment in the adhesive layers.

In some embodiments, the substrate has at least two polymers layers. In some embodiments, the substrate comprises a first polymer layer and a second polymer layer. In some embodiments, substrate additionally comprises an adhesive layer having a top layer and a bottom layer wherein the adhesive top layer is attached to the first polymer layer and the adhesive bottom layer is attached to the second polymer layer. In some embodiments, the adhesive used to bond the first polymer layer to the second polymer layer is selected from the group consisting of fluoropolymers, epoxys acrylics, polyurethanes, vinyl adhesives and mixtures thereof. In some embodiments, the substrate has more than two polymer layers wherein the polymer layers may or may not have adhesive layers between each polymer layer. In some embodiments, the adhesive used to bond the first polymer layer to the second polymer layer comprises a thermally conductive filler. The thermally conductive filler in the adhesive layer may the same or different from the thermally conductive filler used in other layers of the device In some embodiments, the adhesive layer thickness is between (and optionally including) any two of the following thicknesses: 1, 1.25, 2, 3, 4, 5, 6, 7, 8, 9, 10, 11, 12 and 12.5 microns.

In some embodiments, the substrate first polymer layer and second polymer layer comprise two or more additional polymer layers. The additional polymer layers may be the same or different from the first polymer layer and the second polymer layer. In some embodiments, the additional polymer layers may or may not contain a thermally conductive filler, a light absorbing pigment or mixtures thereof. In another embodiment, only some of the additional layers contain a thermally conductive filler, a light absorbing pigment or mixtures thereof. In some embodiments, the thermally conductive filler and light absorbing pigment in the additional polymer layers are the same or different from the thermally conductive filler and light absorbing pigment in the first polymer layer and the second polymer layer.

There is a practical limit to the thickness of the substrate. If the substrate is too thick, thermal dissipation of the device may be adversely affected. If the polymer layers are too thin, dielectric breakdown may occur. The desired thickness of the substrate must balance dielectric properties as well as thermal conductivity. This balance will depend on the electrical application in which the device of the present disclosure is used, the voltage applied and the amount of heat generated. In some embodiments, the substrate thickness is between (and optionally including) any two of the following thicknesses: 8, 12.5, 14, 16, 18, 20, 25, 30, 40, 50, 60, 70, 80, 90, 100, 110, 120, 124 and 150 microns.

Having thin multiple polymer layers has an advantage over a single polymer layer of the same thickness. Multiple layers decrease the chance of having pinhole or other defects (foreign particles, gels, filler or other agglomerates) that could adversely impact the electrical integrity and electrical breakdown performance of a dielectric film. The term “pinhole” herein denotes a small hole that results from non-uniformities in a coating or preparation process. These defects can be a serious issue particularly in thin films in terms of electrical performance unless great care is taken to eliminate them. A single layer film can be made thicker in an attempt to decrease defects or their impact on the film's integrity; however, the use of thick a film in the present disclosure may adversely impact the thermal dissipation of the device. A substrate having thin multiple layers would reduce the impact of pinholes and other defects and also maintain good thermal dissipation.

Polymers of the present disclosure can be made by methods well known in the art and their preparation need not be discussed here. Multiple polymer layers can be prepared either by laminating single layers together with or without a separate adhesive or by coating of a layer on top of one another or by coextrusion processes to prepare multilayer films, or by combinations of these. Utilization of multilayers of polymer helps to greatly eliminate the occurrence of defects that may span the total thickness of the dielectric layer because the likelihood of defects that overlap in each of the individual layers is extremely small and therefore a defect in any one of the layers is much less likely to cause an electrical failure through the entire thickness of the dielectric.

In some embodiments, the adhesive layer is extruded on to the substrate. In some embodiments, the adhesive layer is vacuum laminated to the substrate.

### Thermally Conductive Filler

The term “thermally conductive filler” as used herein refers to any filler having the ability to conduct heat greater than the polymer's ability to conduct heat. The filler can be any shape. In some embodiments, the thermally conductive filler can have an average particle size in a range between (and optionally including) any two of the following sizes: 0.5, 1, 5, 10, 20, 30, 40 50, 60, 70, 80, 90, 100, 125, 150, 175, 200, 250, 300, 350, 400, 450, 500 and 5,000 nanometers, where at least 80, 85, 90, 92, 94, 95, 96, 98, 99 or 100 percent of the dispersed filler is within the above size range(s). In some embodiments, the thermally conductive fillers can require milling and filtration to break up or remove unwanted particle agglomeration which can result in low dielectric strength.

In some embodiments, the thermally conductive filler is selected from a group consisting of silicon dioxide, silicon carbide, titanium dioxide, diamond, beryllium oxide, talc, zinc oxide and mixtures thereof. In another embodiment, the thermally conductive filler is selected from a group consisting of aluminum oxide, boron nitride coated aluminum oxide, aluminum nitride, aluminum oxide coated aluminum nitride, silicon dioxide coated aluminum nitride, boron nitride and mixtures thereof.

There is a practical limit to the amount of thermally conductive filler that can be added. If the amount of thermally conductive filler is too high then adhesion, electrical insulating ability and mechanical properties can be adversely affected. This practical limit will also depend on the polymer. One polymer may be capable of having a high filler loading and maintain acceptable mechanical properties. While another polymer at the same high filler loading may have a decrease in mechanical properties. Therefore the amount of filler must be tailored for the polymer used and the mechanical properties desired.

### Light Absorbing Pigment

The term “light absorbing pigment” as used herein refers any additive that helps protect a polymer composition from the long-term degradation effects from light. In some embodiments, the light absorbing pigment is a UV absorber. In another embodiment, the light absorbing pigment is a UV stabilizer. In yet another embodiment, mixtures of UV absorbers and UV stabilizers are used. In some embodiments, the light absorbing pigment is selected from a least one UV absorber. In another embodiment, the light absorbing pigment is selected from at least one UV stabilizer. In yet another embodiment, mixtures of UV absorbers and UV stabilizers are used. In some embodiments, the light absorbing pigment is selected from the group consisting of carbon black, titanium dioxide, benzotriazoles, benzophenones, hindered amines and mixtures thereof.

There is a practical limit to the amount of light absorbing pigment that can be added. If the amount of pigment is too high then adhesion, electrical insulating ability and mechanical properties can be adversely affected. In some embodiments, the amount of light absorbing pigment in any given layer is between (and optionally including) any two of the following numbers: 0, 5, 10, 15 and 20 weight percent. The thermally conductive filer and/or the light absorbing pigment may be dispersed in the polymer or a polymer precursor material directly, or may be dispersed in solvent prior to dispersion in the polymer or polymer precursor. Any conventional or non-conventional method of manufacturing filled polymer films can be used in accordance with the present disclosure. The manufacture of filled polymer films is well known and need not be further described here.

### Heat Sink

The metal heat sink absorbs and dissipates thermal energy or heat. Heat sinks are used in a wide range of applications wherever efficient heat dissipation is required. Heat sinks function by efficiently transferring thermal energy from an object at a higher temperature to a second object, surrounding air or water, at a lower temperature with a much greater heat capacity. For purposes of this disclosure, the heat sink transfers heat or thermal energy from an electrical component. Efficient function of a heat sink relies on rapid transfer of thermal energy. The heat sinks are typically composed of thermally conducting materials such as aluminum, anodized aluminum or thermally conductive polymers. Their construction can be as simple as a metal plate to a metal device with many fins. The high thermal conductivity of the metal combined with its large surface area result in the rapid transfer of thermal energy to the surrounding, cooler, air. This cools the heat sink and whatever it is in direct thermal contact with. In one embodiment, the heat sink is an aluminum plate.

The metal heat sink of this disclosure has a top surface and a bottom surface, the heat sink top surface being directly bonded, using heat and pressure, to the second adhesive layer bottom surface.

In one embodiment, the device of the present disclosure is a photovoltaic assembly comprising, a photovoltaic cell metalized layer, a first adhesive layer, a substrate, a second adhesive layer and a heat sink. In another embodiment, the device of the present disclosure is a light concentrator photovoltaic assembly comprising, a photovoltaic cell metalized layer, a first adhesive layer, a substrate, a second adhesive layer and a heat sink. The device of the present disclosure may be directly bonded to a photovoltaic cell. The photovoltaic cell is directly bonded to the first adhesive top surface by lamination using sufficient heat and pressure to adhere the first adhesive top surface to the semiconducting layer (metalized layer or contact grid) of a photovoltaic cell. The component or layer of the photovoltaic cell that is adhered to the first adhesive layer top surface will depend on the photovoltaic cell. In some embodiments, the component or layer of the photovoltaic cell that is adhered to the first adhesive layer top surface is monocrystalline silicon or polycrystalline silicon. In some embodiments, it is a silicon wafer layer.

As used herein, the terms “comprises,” “comprising,” “includes,” “including,” “has,” “having” or any other variation thereof, are intended to cover a non-exclusive inclusion. For example, a method, process, article, or apparatus that comprises a list of elements is not necessarily limited only those elements but may include other elements not expressly listed or inherent to such method, process, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of the “a” or “an” are employed to describe elements and components of the disclosure. This is done merely for convenience and to give a general sense of the disclosure. This description should be read to include one or at least one and the singular also includes the plural unless it is obvious that it is meant otherwise.

### EXAMPLES

The present disclosure will be further described in the following examples. Examples are not intended to limit the scope of this disclosure.

| | |
|---|---|
| Kapton ® | A multilayer aromatic polyimide film containing |
| 200 CR | aluminum oxide, 50 microns (2 mil) thick, available |
| | from E. I. du Pont de Nemours and Company, |
| | Wilmington, DE. |
| Bixcure ® | A formulated EVA adhesive from Bixby International |
| | Corporation, Newburyport, MA |
| Elvaloy ® 4170 | Ethylene n-butylacrylate glycidyl methacrylate |
| | (EnBAGMA) terpolymer available from E. I. du Pont |
| | de Nemours and Company, Wilmington, DE. |

### Example 1

Example 1 illustrates the use of a Kapton® 200 CR polyimide film and BixCure® a formulated ethylene vinyl acetate (EVA) copolymer adhesive.

A 50 micron (2 mil) Kapton® 200 CR film was coated with an aqueous dispersion of tetrafluoroethylene hexafluoropropylene which was subsequently dried and cured to a fluoropolymer film of about 2.5 micron (0.1 mil) thickness. Two of these fluoropolymer coated polyimide films are subsequently laminated together with the fluoropolymer layers facing each other to yield a multilayer film of about 105 microns (4.2 mil) total thickness. Onto this composite film, Bixcure was extrusion coated to a thickness of about 25 microns (1 mil) to 75 microns (3 mil). The bonding result between the adhesive and the polyimide film were excellent. Excellent meaning at ambient temperature, the adhesive could not be separated by hand from the substrate without tearing. This adhesive coated polyimide film was subsequently laminated to an aluminum plate and the EVA copolymer layer cured to yield an electrically insulating, thermally conductive device for which the bonding result of the composite film to the aluminum plate were excellent. The composite film with aluminum plate was laminated to the photovoltaic cell. The bonding results to the Photovoltaic cell were excellent. The device was soaked in water at ambient temperature for greater than 12 days. The bonding result of the composite film to the polyimide film, after soaking, was excellent. The bonding result of the composite film to the aluminum plate, after soaking, was peelable. The bonding result of the composite film to the photovoltaic cell, after soaking, was excellent. In combination with the aluminum heat sink, the Kapton CR based composite film is expected to provide excellent electrical insulation performance and very high dielectric breakdown strength while still allowing adequate thermal dissipation performance.

### Example 2

Example 2 illustrates the use of a Kapton® 200 CR polyimide film and Elvaloy 4170 adhesive.

The sample was prepared in a similar manner to example 1.

The bonding result between the adhesive and the polyimide film was excellent. The bonding result of the composite film to the aluminum plate was excellent. The bonding result to the Photovoltaic cell was excellent. The bonding result of the composite film to the polyimide film, after soaking, was excellent. The bonding result of the composite film to the aluminum plate, after soaking, was peelable. The bonding result of the composite film to the photovoltaic cell, after soaking, was excellent.

The flowing examples 3-7 illustrate substrates of the present invention which could have adhesive layers extrusion coated thereon in a similar manner to example 1.

### Example 3

A 20 wt % solution of polysulfonamide polymer (PSA, a polyaramide or aromatic polyamide) was prepared by dissolving polysulfonamide fiber (available as Tanlon™ fiber from Shanghai Tanlon Fiber Co., Ltd., China) in dimethylacetamide (DMAC) at a 1 to 4 weight ratio of PSA to DMAC. A 180 g portion of this solution along with an additional 20 g DMAC and 24 g of alumina filler (Martoxid® MZS-1 from Albermarle Corporation) was blended in a Thinky ARE-250 mixer. The mixture was pressure filtered through a 45 micron filter then degassed under vacuum. Separate portions of this mixture were cast at two different thicknesses onto 9 mil Duofoil™ aluminum release sheets, then dried at about 60-80° C. on a hot plate to give tack free films. The films were separated from the Duofoil, placed on pin frames and placed in an air oven at 100° C. and held for 10 minutes. Then the temperature was ramped to 200° C. and held for 10 min, and then ramped to 320° C. and held there for 10 minutes. After cooling, the films were released from the pin frames. Two filled polysulfonamide (PSA) films containing about 40 wt % alumina of 5.8 and 3.8 mils average thickness resulted.

### Example 4

Similar to Example 3, a 180 g portion of the PSA polymer solution described in Example 3 was blended in a Thinky ARE-250 mixer with an additional 20 g DMAC and 15.43 g of alumina filler (Martoxid® MZS-1). The mixture was pressure filtered through a 45 micron filter then degassed under vacuum. A portion of this solution was cast and dried as described in Example 3. After cooling, the film was released from the pin frame to give a filled polysulfonamide (PSA) film containing about 30 wt % alumina of about 3.0 mil average thickness.

### Example 5

A 200 g portion of Voltatex® 8227 polyamide imide enamel solution (˜27% polymer solids, DuPont Performance Coatings, Wuppertal, Germany) along 23.14 g of alumina filler (Martoxid® MZS-1) was blended in a Thinky ARE-250 mixer. The mixture exhibiting a Brookfield viscosity of about 35 poise was pressure filtered through a 45 micron filter and then degassed under vacuum. A portion of this mixture was cast as described in Example 3, and then the resulting film on a pin frame was placed in an air oven at 100° C. and held for 10 minutes, then ramped to 150° C. and held for 5 min, then ramped to 220° C. and held for 10 min and then ramped to 280° C. and held there for 10 minutes. After cooling, the film was released from the pin frame to give a filled polyamide imide film containing about 30 wt % alumina of about 3.2 mil average thickness.

### Example 6

Fifty (50) g of polyethersulfone (PES) powder were dissolved in 200 g of DMAC utilizing a Thinky ARE-250 mixer. The solution was relatively thin so two additional amounts of PES powder (16.7 g and 19 g) were subsequently mixed in to give a final 30 wt % polymer solution. A 200 g portion of this solution was subsequently blended with 25.7 g of MZS-1 alumina in the Thinky mixer. The mixture was pressure filtered through a 45 micron filter and then degassed under vacuum. Brookfield viscosity was approximately 80 poise. Portions of this mixture were cast as in Example 3. The resulting films on pin frames were place in an air oven at 100° C. and held for 10 minutes, then ramped to 150° C. and held for 5 min, then ramped to 200° C. and held for 10 min and then ramped to 250° C. and held there for 10 minutes. After cooling, the film was released from the pin frame to give a filled polyether sulfone film containing about 30 wt % alumina of about 4.1 mil average thickness.

### Example 7

Fifty (50) g of Torlon® 4000TF polyamide imide (PAI) powder from Solvay Advanced Polymers was dissolved in 150 g of DMAC utilizing a Thinky ARE-250 mixer to give a 25 wt % polymer solution. To this solution 21.4 g of MZS-1 alumina were added with blending in the Thinky mixer. The mixture was pressure filtered through a 45 micron filter and then degassed under vacuum. Brookfield viscosity was approximately 130 poise. A portion of this mixture was cast as described in Example 3, and then the resulting film on a pin frame was placed in an air oven at 100° C. and held for 10 minutes, then ramped to 150° C. and held for 5 min, then ramped to 200° C. and held for 10 min and then ramped to 300° C. and held there for 10 minutes. After cooling, the film was released from the pin frame to give a filled polyamide imide film containing about 30 wt % alumina of about 3.4 mil average thickness.

Note that not all of the activities described above in the general description or the examples are required, that a portion of a specific activity may not be required, and that further activities may be performed in addition to those described. Still further, the order in which each of the activities are listed are not necessarily the order in which they are performed. After reading this specification, skilled artisans will be capable of determining what activities can be used for their specific needs or desires.

In the foregoing specification, the invention has been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense and all such modifications are intended to be included within the scope of the invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims.

When an amount, concentration, or other value or parameter is given as either a range, preferred range or a list of upper values and lower values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

What is claimed is:

1. A device for thermally cooling while electrically insulating comprising:
A. a first adhesive layer having a top surface and a bottom surface, the first adhesive layer comprising an amount from 68 to 100 weight percent vinyl or acrylic based polymer;
B. a substrate comprising at least one polymeric layer comprising:
i. 30 to 95 weight percent of a polymer selected from the group consisting of polyamide imides, polyether imides, polyaramids, polyamides, polysulfones, polyether ketones, liquid crystal polymers, polyesters, fluoropolymers, silicone resins, epoxy resins, cyanate esters, bismaleimide resins, bistriazines resins, polyphenylene sulfide, polyphenylene oxide and mixtures thereof; and
ii. 5 to 70 weight percent thermally conductive filler, wherein the first adhesive bottom surface is directly bonded to the substrate;
C. a second adhesive layer having a top surface and a bottom surface, the second adhesive layer top surface being directly bonded to the substrate opposite of the first adhesive layer; the second adhesive layer comprising an amount from 68 to 100 weight percent vinyl or acrylic based polymer;
D. a metal heat sink having a top surface and a bottom surface, the heat sink top surface being directly bonded to the second adhesive layer bottom surface.

2. A device in accordance with claim 1, wherein substrate additionally comprises from 1 to 20 weight percent of a light absorbing pigment.

3. A device in accordance with claim 1, wherein the first adhesive layer and the second adhesive layer additionally comprise a filler selected from the group consisting of thermally conductive filler, light absorbing pigment and mixtures thereof.

4. A device in accordance with claim 1, wherein the first adhesive layer and second adhesive layers are independently selected from the group consisting of:
ethylene vinyl acetate copolymer with adhesion promotor,
ethylene vinyl acetate glycidyl acrylate terpolymer,
ethylene vinyl acetate glycidyl methacrylate terpolymer,
ethylene alkyl acrylate copolymers with adhesion promotor,
ethylene alkyl methacrylate copolymers with adhesion promotor,
ethylene glycidyl acrylate,
ethylene glycidyl methacrylate,
ethylene alkyl acrylate glycidyl acrylate terpolymer,
ethylene alkyl methacrylate glycidyl acrylate terpolymer,
ethylene alkyl acrylate maleic anhydride terpolymers,
ethylene alkyl methacrylate maleic anhydride terpolymers
ethylene alkyl acrylate glycidyl methacrylate terpolymers,
ethylene alkyl methacrylate glycidyl methacrylate terpolymers,
alkyl acrylate acrylonitrile acrylic acid terpolymers,
alkyl acrylate acrylonitrile methacrylic acid terpolymers,
ethylene acrylic acid copolymer including salts thereof,
ethylene methacrylic acid copolymer including salts thereof,
alkyl acrylate acrylonitrile glycidyl methacrylate terpolymers,
alkyl methacrylate acrylonitrile glycidyl methacrylate terpolymers,
alkyl acrylate acrylonitrile glycidyl acrylate terpolymers,
alkyl methacrylate acrylonitrile glycidyl acrylate terpolymers,
polyvinyl butyral,
ethylene alkyl acrylate methacrylic acid terpolymers including salts thereof,
ethylene alkyl methacrylate methacrylic acid terpolymers including salts thereof,
ethylene alkyl acrylate acrylic acid terpolymers including salts thereof
mixtures thereof,
ethylene alkyl methacrylate acrylic acid terpolymers including salts thereof,
ethylene ethyl hydrogen maleate,
ethylene alkyl acrylate ethyl hydrogen maleate,
ethylene alkyl methacrylate ethyl hydrogen maleate,
and mixtures thereof.

5. A device in accordance with claim 1, wherein the substrate comprises a first polymeric layer and a second polymeric layer.

6. A device in accordance with claim 5, wherein the substrate additionally comprises an adhesive layer having a top layer and a bottom layer wherein the adhesive top layer is attached to the first polymeric layer and the adhesive bottom layer is attached to the second polymeric layer.

7. A device in accordance with claim 6, wherein the adhesive layer is selected from the group consisting of fluoropolymers, epoxys acrylics, polyurethanes, vinyl adhesives and mixtures thereof.

8. A device in accordance with claim 6, wherein the adhesive layer additionally comprised a thermally conductive filler.

9. A device in accordance with claims 1 wherein the thermally conductive filler is selected from the group consisting of aluminum oxide, boron nitride coated aluminum oxide, aluminum nitride, aluminum oxide coated aluminum nitride, silicon dioxide coated aluminum nitride, boron nitride and mixtures thereof.

10. A device in accordance with claims 1, wherein the light absorbing pigment is selected from the group consisting of carbon black, titanium dioxide, benzotriazoles, benzophenones, hindered amines and mixtures thereof.

11. A device in accordance with claim 1 wherein the first adhesive layer and the second adhesive layer thickness are each from 6.25 to 75 microns.

12. A device in accordance with claim 1 wherein the substrate thickness is from 8 to 150 microns.

13. A device in accordance with claim 1 further comprising photovoltaic cell directly bonded to the top surface of the first adhesive layer.

14. A photovoltaic assembly comprising:
A. A photovoltaic cell metalized layer;
B. a first adhesive layer having a top surface and a bottom surface, the first adhesive layer comprising an amount from 68 to 100 weight percent vinyl or acrylic based polymer, wherein the photovoltaic cell is directly bonded to the first adhesive top surface;
C. a substrate comprising at least one polymeric layer comprising:
i. 30 to 95 weight percent of a polymer selected from the group consisting of polyamide imides, polyether imides, polyaramids, polyamides, polysulfones, polyether ketones, liquid crystal polymers, polyesters, fluoropolymers, silicone resins, epoxy resins, cyanate esters, bismaleimide resins, bistriazines resins, polyphenylene sulfide, polyphenylene oxide and mixtures thereof; and
ii. 5 to 70 weight percent thermally conductive filler,
wherein the first adhesive bottom surface is directly bonded to the substrate;
D. a second adhesive layer having a top surface and a bottom surface, the second adhesive layer top surface being directly bonded to the substrate opposite of the first adhesive layer; the second adhesive layer comprising an amount from 68 to 100 weight percent vinyl or acrylic based polymer;
E. a metal heat sink having a top surface and a bottom surface, the heat sink top surface being directly bonded to the second adhesive layer bottom surface.

15. A light concentrator photovoltaic assembly comprising:
A. A photovoltaic cell metalized layer;
B. a first adhesive layer having a top surface and a bottom surface, the first adhesive layer comprising an amount from 68 to 100 weight percent vinyl or acrylic based polymer, wherein the photovoltaic cell metalized component is directly bonded to the first adhesive top surface;
C. a substrate comprising at least one polymeric layer comprising:
i. 30 to 95 weight percent of a polymer selected from the group consisting of polyamide imides, polyether imides, polyaramids, polyamides, polysulfones, polyether ketones, liquid crystal polymers, polyesters, fluoropolymers, silicone resins, epoxy resins, cyanate esters, bismaleimide resins, bistriazines resins, polyphenylene sulfide, polyphenylene oxide and mixtures thereof; and
ii. 5 to 70 weight percent thermally conductive filler,
wherein the first adhesive bottom surface is directly bonded to the substrate;
D. a second adhesive layer having a top surface and a bottom surface, the second adhesive layer top surface being directly bonded to the substrate opposite of the first adhesive layer; the second adhesive layer comprising an amount from 68 to 100 weight percent vinyl or acrylic based polymer;
E. a metal heat sink having a top surface and a bottom surface, the heat sink top surface being directly bonded to the second adhesive layer bottom surface.
